(19) United States
(12) Patent Application Publication
(10) Pub. No.: US 2025/0338628 A1
(43) Pub. Date: Oct. 30, 2025

(54) CELL ARRANGEMENT FOR SEMICONDUCTOR DEVICE LAYOUT

(71) Applicant: Arm Limited, Cambridge (GB)

(72) Inventors: Chihwei Huang, Austin, TX (US); Yew Keong Chong, Austin, TX (US); Sriram Thyagarajan, Austin, TX (US)

(21) Appl. No.: 18/821,978

(22) Filed: Aug. 30, 2024

Related U.S. Application Data
(60) Provisional application No. 63/639,535, filed on Apr. 26, 2024.

(51) Int. Cl. H01L 27/02; H01L 29/06

(52) U.S. Cl. CPC H10D 89/10; H10D 62/121

(57) ABSTRACT

Subject matter disclosed herein relates generally to semiconductor devices, and, more particularly, to semiconductor device cell layout.

This application claims priority from U.S. Provisional Patent Application Ser. No. 63/639,535, filed Apr. 26, 2024, entitled “Cell Arrangement for Semiconductor Device Layout,” incorporated herein by reference in its entirety.

### BACKGROUND

### Field

Subject matter disclosed herein relates generally to semiconductor devices, and, more particularly, to semiconductor device cell layout.

### Information

In some instances, integrated circuits may be designed based on desired functions using cells from a cell library which may be combined using computer-based layout tools to form desired circuits. Also, in some instances, cell libraries may be based on Gate-All-Around (GAA) FET-based design architectures, as one example of a variety of current and/or future technologies, which have gained increasing acceptance in response to continued desires for lower power, increased performance, and/or more compact designs. Also, in some instances, as device heights become shorter, diffusion structures may become smaller. Smaller diffusion structures may reduce or limit performance. Further, for example, reduced performance may prohibit continued reductions in semiconductor process feature size.

### BRIEF DESCRIPTION OF THE DRAWINGS

Claimed subject matter is particularly pointed out and distinctly claimed in the concluding portion of the specification. However, both as to organization and/or method of operation, together with objects, features, and/or advantages thereof, it may best be understood by reference to the following detailed description if read with the accompanying drawings in which:

FIG. 1 is an illustration of an example GAA FET transistor structure, in accordance with an embodiment;

FIG. 2 is an illustration depicting example double-height cells, in accordance with an embodiment;

FIG. 3 is an illustration depicting an example double-height cell and an example 1.5H cell, in accordance with an embodiment;

FIG. 4 is a chart showing example characteristics of example cell types, in accordance with an embodiment;

FIG. 5 is an illustration showing an example layout including standard-height cells, double-height cells, and 1.5H cells, in accordance with an embodiment;

FIG. 6 is an illustration depicting example cells, including example cell filler options, in accordance with an embodiment;

FIG. 7 is an illustration depicting an example cell, including example cell filler options, in accordance with an embodiment;

FIG. 8 is an illustration depicting example cells, including example cell filler options, in accordance with an embodiment; and

FIG. 9 is an illustration depicting an example cell layout including power rails, in accordance with an embodiment.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### DETAILED DESCRIPTION

References throughout this specification to one implementation, an implementation, one embodiment, an embodiment, and/or the like means that a particular feature, structure, characteristic, and/or the like described in relation to a particular implementation and/or embodiment is included in at least one implementation and/or embodiment of claimed subject matter. Thus, appearances of such phrases, for example, in various places throughout this specification are not necessarily intended to refer to the same implementation and/or embodiment or to any one particular implementation and/or embodiment. Furthermore, it is to be understood that particular features, structures, characteristics, and/or the like described are capable of being combined in various ways in one or more implementations and/or embodiments and, therefore, are within intended claim scope. In general, of course, as has always been the case for the specification of a patent application, these and other issues have a potential to vary in a particular context of usage. In other words, throughout the patent application, particular context of description and/or usage provides helpful guidance regarding reasonable inferences to be drawn; however, likewise, “in this context” in general without further qualification refers to the context of the present patent application.

As mentioned, integrated circuits may be designed based on desired functions using cells from a cell library which may be combined using computer-based layout tools to form desired circuits. Also, in some instances, cell libraries may be based on Gate-All-Around (GAA) FET-based design architectures, as one example of a variety of current and/or future technologies, which have gained increasing acceptance in response to continued desires for reduced power, increased performance, and/or more compact designs. Also, in some instances, as device heights become shorter, diffusion structures may become smaller. Smaller diffusion structures may reduce or limit performance in some circumstances, for example. Further, for example, reduced performance may inhibit continued reductions in semiconductor process feature size.

To address, at least in part, the challenges discussed above, embodiments are described herein. For example, in an embodiment, an integrated circuit device may comprise a first cell having a height that is 1.5 times of a standard cell height, wherein the first cell comprises a first diffusion structure of a first diffusion type aligned in a first direction and a second diffusion structure of a second diffusion type aligned in the first direction. In an embodiments, an integrated circuit device may further comprise a second cell having a second height that is 0.5 or 1.5 times a standard cell height, wherein a top portion of the second cell abuts a bottom portion of the first cell. In implementations, a width of a diffusion structure may be greater than a width of a second diffusion structure, and at least a portion of a first diffusion structure may be positioned across a power rail, for example.

In implementations, a first diffusion type may comprise a P-type diffusion and a second diffusion type may comprise an N-type diffusion, for example. In other implementations, a first diffusion type may comprise an N-type diffusion and a second diffusion type may comprise a P-type diffusion, for example.

In implementations, a first diffusion structure may comprise a first plurality of nanosheets and/or nanowires and a second diffusion structure may comprise a second plurality of nanosheets and/or nanowires, for example. In implementations, a width of a first diffusion structure may comprise a nanosheet width (NSW) of between approximately 30-80 nm. For example, a width of a first diffusion structure may comprise an NSW of approximately 65 nm, in implementations. Also, in implementations, a width of a second diffusion structure may comprise a nanosheet width (NSW) of between approximately 10-50 nm. For example, a width of a second diffusion structure may comprise a nanosheet width (NSW) of approximately 35 nm, in implementations. Of course, subject matter is not limited in scope in these respects.

In implementations, an integrated circuit may further comprise a layout including a first 1.5H cell and a second 0.5H or 1.5H cell, wherein a bottom portion of the second cell abuts a top portion of a third cell having a height that is an integer multiple of a standard cell height or an even integer multiple of 1.5 times that standard cell height, for example. In implementations, a layout may further comprise at least a fourth 1.0H cell and at least a fifth 2.0H cell abutting left/right one or more of the first and second cells, for example. In implementations, wherein a first cell abuts left/right a fourth 1.0H cell, a layout further may comprise a first filler cell to enable a transition from one or more diffusion structures of a 1.0H cell to one or more diffusion structures of a 1.5H cell, for example. In implementations, a first filler cell may comprise a 1.5H filler cell, for example.

Further, in implementations, wherein a second 0.5H or 1.5H cell abuts left/right at least a fifth 2.0H cell, a layout may further comprise a second filler cell to enable transitions from one or more diffusion structures of at least a fifth 2.0H cell to one or more diffusion structures of a second 0.5H or 1.5H cell, for example. In implementations, a second filler cell may comprise a 2.0H filler cell, for example. Also, in implementations, a layout may comprise a plurality of 1.0H cells abutting left/right a plurality of 1.5H cells, and a layout may further comprise a plurality of 0.5H filler cells and a plurality of 1.0H filler cells to enable transitions from a plurality of diffusion structures of a plurality of 1.0H cells to a plurality of diffusion structures of a plurality of 1.5H cells, for example.

In implementations, a layout may comprise a plurality of 1.0H cells abutting left/right a plurality of 1.5H cells, and/or a layout may also comprise a plurality of 1.5H filler cells to enable transitions from a plurality of diffusion structures of the plurality of 1.0H cells to a plurality of diffusion structures of a plurality of 1.5H cells, for example. Also, in implementations, a layout may further comprise one or more third cells abutting left/right one or more fourth cells with no filler cells to transition between the one or more third cells and the one or more fourth cells, for example. In implementations, an integrated circuit may further comprise one or more 0.5H cells or 2.5H cells, or any combination thereof, for example. Further, in implementations, at least the first cell may be implemented utilizing GAA FET, finFET, or CFET technologies, or any combination thereof, for example.

Embodiments may also include a method, comprising: forming a first cell having a height that is 1.5 times of a standard cell height, wherein the first cell comprises a first diffusion structure of a first diffusion type aligned in a first direction and a second diffusion structure of a second diffusion type aligned in the first direction; and forming a second cell having a second height that is 0.5 or 1.5 times a standard cell height, wherein a top portion of the second cell abuts a bottom portion of the first cell, for example.

Embodiments may additionally include a non-transitory computer-readable medium to store computer-readable code for fabrication of an apparatus comprising: a first cell having a height that is 1.5 times of a standard cell height, wherein the first cell comprises a first diffusion structure of a first diffusion type aligned in a first direction and a second diffusion structure of a second diffusion type aligned in the first direction; and a second cell having a second height that is one of 0.5 or 1.5 times the standard cell height, wherein a top portion of the second cell abuts a bottom portion of the first cell.

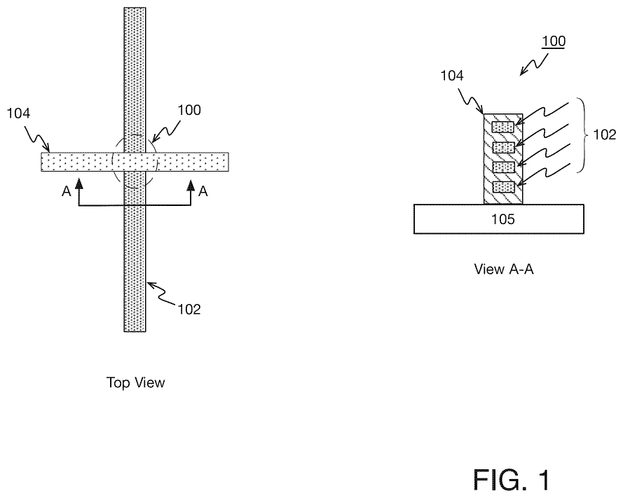

As utilized herein, Gate-All-Around (GAA) FET refers to a cell architecture of a semiconductor device characterized at least in part by pluralities of nanowires and/or nanosheets of one or more diffusion types. GAA FET cell architecture may further be characterized at least in part by nanowires and/or nanosheets being surrounded by a gate structure on all four sides, for example. In some respects, GAA FET transistor architecture may share some characteristics with FinFET cell architecture, with one possible difference being that in GAA FET nanowires and/or nanosheets may be stacked one on top of another (again, with each nanowire and/or nanosheet surrounded on all four sides by a gate structure, for example). See, for example, FIG. 1. Although GAA FET technologies are mentioned herein, subject matter is not limited in scope in this respect. For example, subject matter described herein may be applicable to any of a range of technologies that are currently existing and/or yet to be developed. As one non-limiting example, finFET technologies may be employed in embodiments. Embodiments may also find advantageous use in CFET technologies, as another non-limiting example.

“Nanowire” and/or “nanosheet” and/or the like refers to an elongated and/or linear diffusion structure of a substantially rectangular cross-section, for example. Although the term “nanosheet” is generally utilized herein, the term as utilized herein is meant to include nanowires. For example, FIG. 1 depicts an example layout view of an embodiment 100 of an example GAA FET transistor structure. A top view and a cross-sectional view are depicted. In an embodiment, a GAA FET transistor structure 100 may comprise one or more nanosheets 102 of a particular diffusion type. For example, nanosheets 102 may comprise an n-type diffusion material, in an embodiment. In other embodiments, nanosheets 102 may comprise a p-type diffusion material. In an embodiment, nanosheets 102 may be formed of any of a variety of materials including, for example, silicon, silicon germanium, germanium, etc., to name but a few examples. In an implementation, nanosheets 102 may be stacked over a substrate 105. Further, in an embodiment, a gate electrode, such as gate electrode 104, may comprise one or more electrically conductive materials such as, for example, a film of titanium nitride and/or tantalum nitride covered by polysilicon. Also, although FIG. 1 depicts nanosheets 102 having substantially rectangular cross-sections stacked one on top of another over substrate 105, other embodiments may include nanosheets of different shapes. For example, nanosheets may have triangular or circular cross-sections. Of course, subject matter is not limited in scope in these respects.

In some instances, a cell library may include one or more standard-height cells. As used herein, “standard-height” refers to a particular height specified for a particular cell library. For example, a cell having a “standard” height may be said to comprise a “standard-height,” “single-height,” and/or a “1.0-height” (1.0H) cell. A standard cell height may be dependent on the technology being implemented which may include, but are not limited to, GAA FET, finFET, and/or CFET technologies, for example. In an example cell library, a standard height cell may have a height of 140 nm, although subject matter is not limited in scope in this respect. In an embodiment, a cell library may include single-height cells of varying widths. Also, in an embodiment, a cell library may include cells having heights other than a standard height. For example, as discussed below, an example semiconductor device layout may include one or more single-height cells and/or one or more double-height (2.0H) cells. Cells of other heights may also be incorporated.

For example, to address the challenges mentioned above with respect to reduced performance due to diffusion structures becoming smaller as device heights become shorter, a 1.5-height (1.5H) cell may be introduced. As mentioned, in some instances, as device heights become shorter, diffusion structures may become smaller. Smaller diffusion structures may reduce or limit performance. Also, for example, GAA FET-type cell architecture may, in some circumstances, have limited diffusion structure sizes to choose from in designing a circuit. This impact may be bigger in the shorter architectures. For example, in some architectures (e.g., H140) nanosheet width (NSW) may be restricted to specified sizes (e.g., 15 nm or 25 nm). In some instances, the beta ratio may be fixed and this may limit the performance of skewed cells (e.g., NAND cells, NOR cells, AND-OR-Invert (AOI) cells, OR-AND-Invert (OAI) cells, etc.), for example. As discussed more fully below, a one and a half height (1.5H) cell may be introduced to address these challenges.

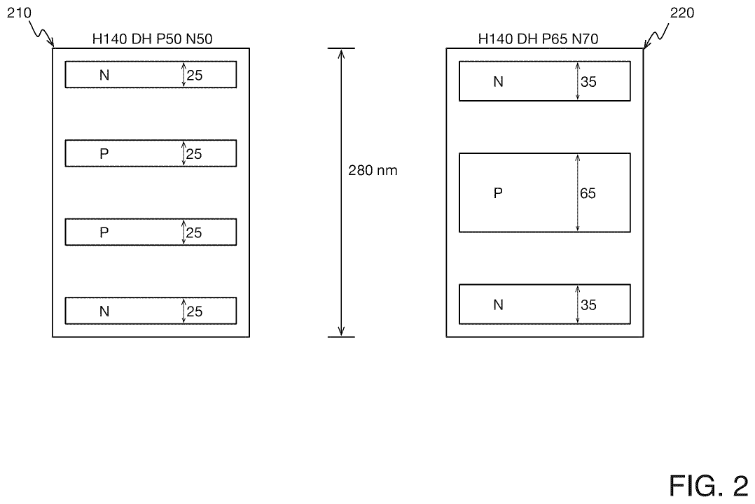

FIG. 2 is an illustration depicting example double-height cells 210 and 220, in accordance with an embodiment. Example double-height (2.0H) cell 210 includes two N-type diffusion structures (e.g., nanosheets) and two P-type diffusion structures. For this example, a width of diffusion structures may be approximately 25 nm. By doubling each of the N-type and P-type diffusion structures, an effective width of each diffusion type may be 50 nm, for example. In an embodiment, a double-height cell may have an overall height of 280 nm, although subject matter is not limited in this respect.

For GAA FET-type cells, for example, diffusion structures may comprise nanosheets, for example, and a width of a diffusion structure may be referred to as nanosheet width (NSW). Although the term nanosheet width (NSW) may be utilized herein to discuss diffusion structure width, embodiments are not limited to nanosheet diffusion structures. Similarly, embodiments are not limited in scope of GAA FET-type cell architectures. As mentioned, embodiments may also be utilized advantageously with finFET technologies, CFET technologies, and/or other technologies currently existing or yet to be developed.

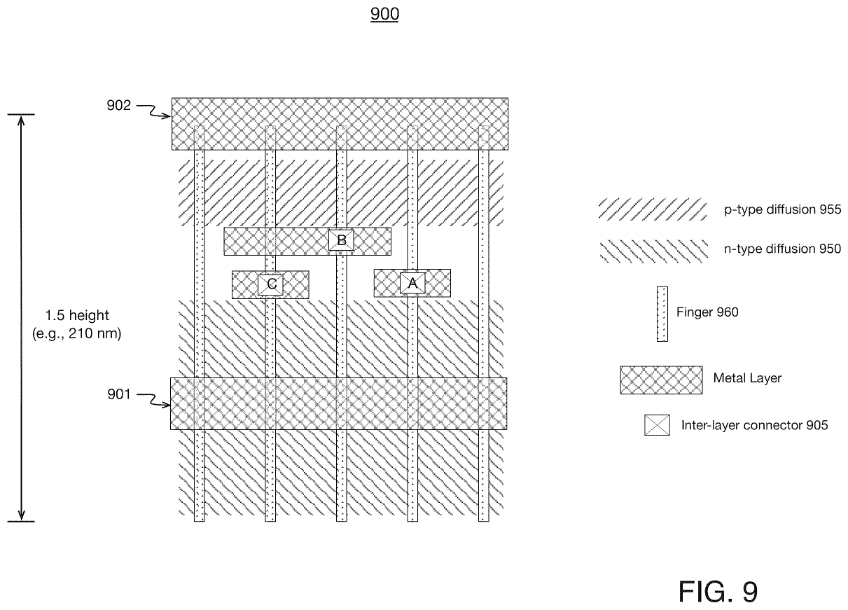

In implementations, to help improve performance, for example, it may be beneficial and/or advantageous to increase an effective diffusion structure width. For example, if an NSW can go across power rails (see FIG. 9, for example), a larger NSW may be achieved. For an example 2.0H cell, such as example 2.0H cell 220 depicted in FIG. 2, an NSW for N-type diffusion structures may be increased to 35 nm, for example, and two P-type diffusion structures show in cell 210 may be combined into a single larger structure having an NSW of approximately 65 nm for cell 220, for example. For cell 220, in implementations, a total NSW for N-type diffusion may be approximately 70 nm (e.g., 2×35 nm) and a total NSW for P-type diffusion may be approximately 65 nm, for example. In embodiments, such an implementation may be referred to as NSW Extension Across Power Rail, for example. See, for example, FIG. 9. It should be noted that NSW figures and/or measurements discussed herein are merely examples and subject matter is not limited in scope in these respects. Foundries, for example, may have the option to implement other NSW for P-type and/or N-type diffusion structures.

As mentioned, the various measurement values mentioned herein (e.g., cell height, NSW, etc.) are merely examples, and subject matter is not limited in scope in these respects. Also, it should be noted that examples depicted in the figures may not be to proportion, but are rather presented in a manner to facilitate description and/or explanation.

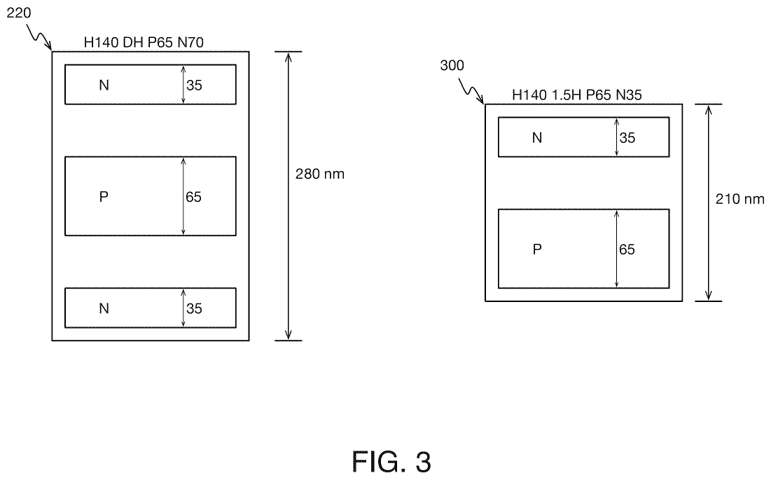

FIG. 3 is an illustration again depicting example layout of a double-height cell 220 and also depicting an example layout for a 1.5H cell 300, in accordance with an embodiment. Example 2.0H cell 220 is described above in connection with FIG. 2. As discussed above, example 2.0H cell 220 may have an effective NSW of approximately 70 nm for an N-type diffusion structure and a P-type diffusion structure may have an NSW of approximately 65 nm, for example. FIG. 3 also depicts 1.5H cell 300. As mentioned above, a 1.5H cell may be beneficial in helping to address some of the challenges mentioned above. For 1.5H cell 300, in implementations, an N-type diffusion structure may have an NSW of between approximately 10-50 nm, such as 35 nm, and/or a P-type diffusion structure may have an NSW of between approximately 30-80 nm, such as 65 nm, for example. Of course, subject matter is not limited in scope to these example NSW values. It may be noted that 1.5H cell 300 may comprise a single N-type diffusion structure as compared with two N-type diffusion structures of example 2.0H cell 220, for example. As depicted in FIG. 3, a 1.5H cell of an example cell library may have an overall height of 210 nm, although subject matter is not limited in scope in this respect.

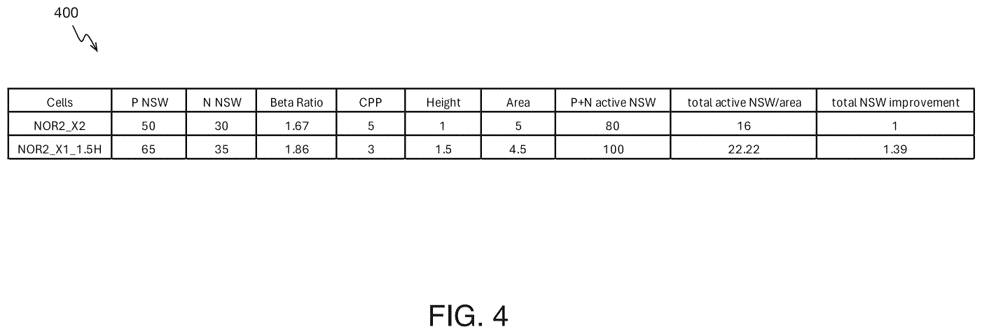

FIG. 4 is a chart 400 showing example characteristics of example cell types, in accordance with one or more embodiments. For the example depicted in FIG. 4, example chart 400 compares a NOR2_X2 type cell with a NOR2_X1_1.5H type cell, in implementations. For this example, a NOR2_X2 type cell may comprise a single-height cell with a CPP (poly) width of 5, in implementations. By contrast, the NOR2_X1_1.5H type cell comprises a 1.5H cell with a CPP width of 3, for example.

As indicated in chart 400, a NOR2_X2 cell may have a P-type nanosheet width (NSW) of 50 nm and an N-type NSW of 30 nm, in implementations. As utilized herein, NSW is generally meant to denote a width of a diffusion structure, including, but not limited to, a nanosheet. As further indicated in chart 400, a NOR2_X2 cell may have a beta ratio of 1.67 (e.g., 50 nm/30 nm) and an area (CPP*Height) of 5 (e.g., 5*1), for example. Further, a NOR2_X2 cell may have a P+N active NSW of 80 nm and/or a total active NSW/area of 16 (e.g., 80/5), in implementations. Because a NOR2_X2 cell is being used as a baseline in a comparison with a NOR2_X1_1.5H cell, the total NSW improvement is shown as 1, for example.

Looking again at chart 400, a NOR2_X1_1.5H cell may have a P-type NSW of 65 nm and an N-type NSW of 35 nm, in implementations. See, for example, cell 300 of FIG. 3. A beta ratio for a NOR2_X1_1.5H cell may be 1.86 (e.g., 65 nm/35 nm) and an area (CPP*Height) may be 4.5 (e.g., 3*1.5), for example. A P+N active NSW for a NOR2_X1_1.5H cell may be 100 nm (e.g., 65 nm+35 nm) and a total active NSW/area may be 22.22 (e.g., 100/4.5), in implementations. Comparing a total active NSW of a NOR2_X1_1.5H cell against a NOR2_X2 cell, for example, a total NSW improvement of 1.39 may be calculated, in implementations. Of course, measurements described in connection with the example cells of chart 400 are merely examples, and subject matter is not limited in scope in these respects.

It may be observed that a NOR2_X1_1.5H cell may have more NSW on N-type and/or P-type diffusion structures as compared to a single height NOR2_X2 cell, in implementations. Also, for example, a beta ratio may be more skewed and/or an area may be smaller. As also noted, an increase in active region per cell area of 39% may be achieved (e.g., total NSW improvement of 1.39), in implementations. A technique of NSW extension across power rail, as discussed above, may be utilized in one or more embodiments to implement a variety of skewed cell types including, for example, NAND cells, NOR cells, AOI cells, OAI cells, etc. In implementations, a skewed INV cell may be utilized advantageously (e.g., rising CLK).

Although the example cells discussed in chart 400 are assumed to be implemented as P65/N35 for a 1.5H cell, other dimensions and/or measurements are possible, in implementations. For example, a foundry may utilize an even more skewed ratio (e.g., P70/N30), in implementations. Also, although the example cells, layouts, etc. show particular arrangements and/or measurements, for example, for N-type and P-type diffusion structures, other example arrangements and/or layouts, for example, may swap N-for-P and P-for-N, in embodiments. For example, in implementations, N-type and P-type diffusion structures of example cell 300 may be swapped such that a larger diffusion structure may be N-type and another diffusion region may be P-type. Again, subject matter is not limited in scope in these respects.

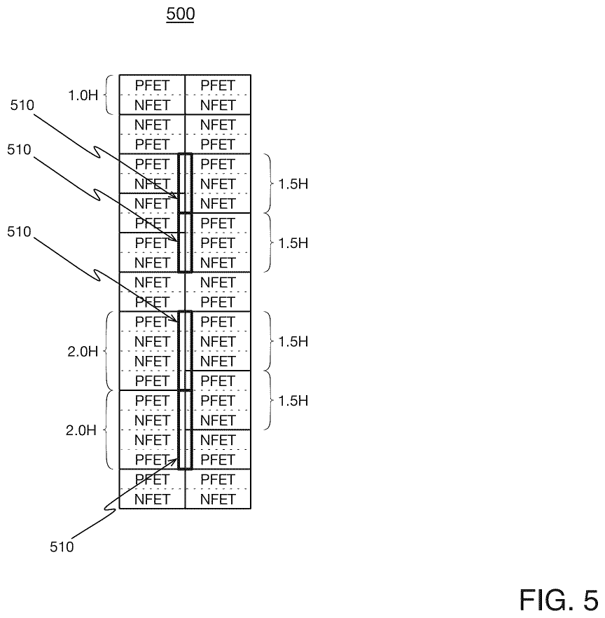

FIG. 5 is an illustration showing an example GAA FET layout 500 including standard-height cells, double-height cells, and 1.5H cells, in accordance with an embodiment. In implementations, a 1.5H cell, such as cell 300, may have one slightly larger NSW on one diffusion structure and a much larger NSW on another diffusion structure (e.g., as compared with a single-height cell). In implementations, for top/bottom abutment, a 1.5H cell may be specified to abut a regular cell on one side and to abut another 1.5H cell on another side. See, for example, example layout 500 wherein each 1.5H cell abuts a single-height cell at one end (top or bottom) and abuts another 1.5H cell at another end (e.g., top or bottom). For left/right abutment, in implementations, if a 1.5H cell abuts a 1.0H cell or a 2.0H cell, a filler cell may be utilized to enable a transition from a diffusion structure of the 1.0H cell or the 2.0H cell to the larger diffusion structure of the 1.5H cell. See filler cells 510 of example layout 500. In implementations, place and route (PnR) tools may be enhanced to accomplish the aforementioned transitions.

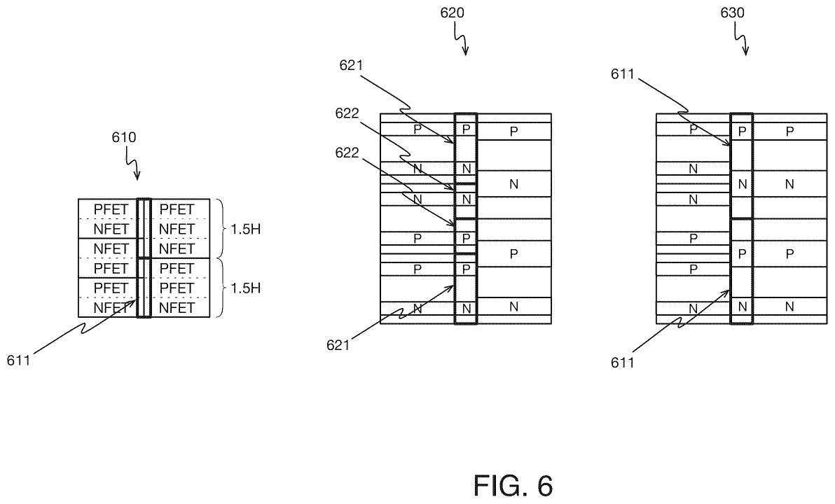

FIG. 6 is an illustration depicting example 1.5H cell filler options, in accordance with one or more embodiments. As depicted in FIG. 6, filler cells to enable transitions for 1.5H cells may be implemented as combinations of single-height filler cells, half-height filler cells, and/or 1.5H filler cells, for example.

For layout 610, for example, 1.5H filler cells 611 may be utilized to provide transitions between diffusion structures of 1.5H cells and diffusion structures of 1.0H cells, in implementations. Also, for layout 620, 1.0H filler cells 621 and 0.5H filler cells 622 may be utilized to provide transitions between diffusion structures of 1.5H cells and diffusion structures of the 1.0H cells, in implementations. Layout 630 of FIG. 6 provides another example of 1.5H filler cells 611 being utilized to provide transitions between diffusion structures of 1.5H cells and diffusion structures of 1.0H cells, in implementations. It may be noted that the NSW jogging depicted in the example layouts of FIG. 6 and other figures are conceptual, and may not be tied to process design kit (PDK).

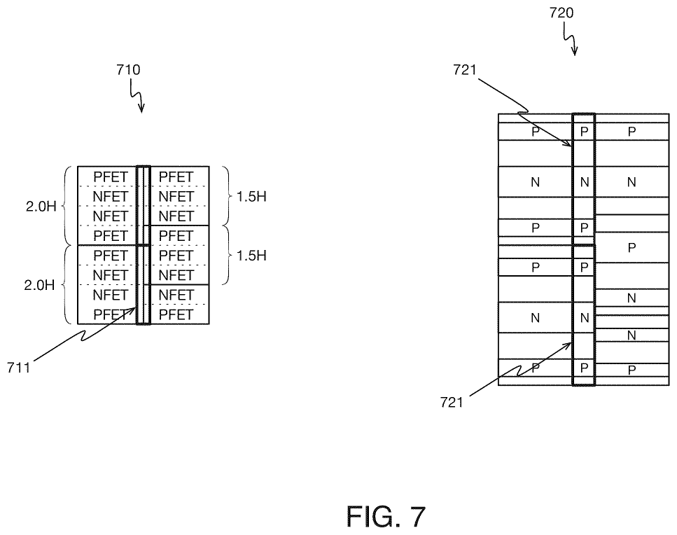

FIG. 7 is an illustration depicting an example 2.0H to 1.5H cell transition, including example filler cell options, in accordance with one or more embodiments. As depicted in FIG. 7, for circumstances in which 2.0H cells abut other 2.0H cells top/bottom, a total height of a combination may be 4.0H, in implementations. It may be seen that 4H may be equivalent to 2×1.5H+1.0H, in implementations. As shown in FIG. 7 for example cells 710 and/or 720, 2.0H filler cells 711 and/or 721 may be utilized to affect a transition between diffusion structures of 1.5H cells and diffusion structures of 2.0H cells, in implementations. Again, NSW jogging depicted in FIG. 7 is conceptual, and may not be tied to a PDK, in implementations.

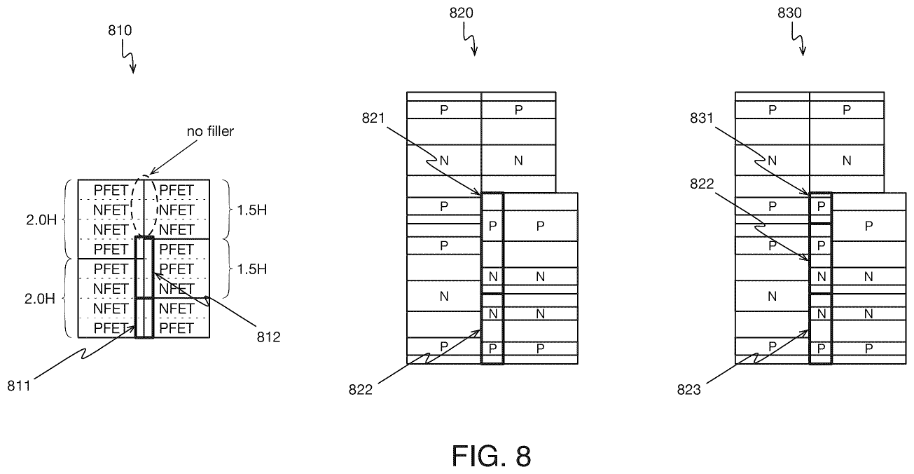

FIG. 8 is an illustration depicting example 2.0H and 1.5H GAA FET cells including example transitions, in accordance with one or more embodiments. In the example of FIG. 7 discussed above, two 2.0H filler cells may be utilized to transition between 1.5H cells and 1.0H cell on the right side of the layout and the abutting 2.0H cells on the left side of the layout. However, for the example depicted in FIG. 8, a PnR tool may be designed, enhanced, etc., to identify compatible edges and remove or avoid unneeded filler cells. For example cells 810, 820, and/or 830 depicted in FIG. 8, no filler cells are needed between the uppermost P-type diffusion structures of the left and right sides of the layout (e.g., the uppermost 2.0H cell and the uppermost 1.5H cell) and also the uppermost N-type diffusion structures of the left and right sides of the layout, in implementations. See the area labeled “no filler” for example cell 810 (note that similar no filler areas are depicted in examples 820 and 830), for example. For the remaining transitions, 1.5H filler cells 812 and 821, 1.0H filler cells 811 and 822, and/or 0.5H filler cells 831 may be utilized to provide transitions, in implementations.

FIG. 9 is an illustration depicting an embodiment 900 of an example 1.5H cell layout for an example cell library. In an embodiment, example layout 900 may include a P-type diffusion structure 955 and/or an N-type diffusion structure 950. Further, in an embodiment, example 1.5H cell layout 900 may include a plurality of fingers, such as fingers 960, aligned in a direction that is substantially orthogonal to structures 955 and/or 950. In embodiments, cell layout 900 may comprise a metal layer including input terminals A, B, and C, as well as a power rail 901 and/or a power rail 902. It may be noted that in implementations one or more diffusion structures, such as N-type diffusion structure 950, may extend across one or more power rails, such as power rail 901. In implementations, power rails 901 and/or 902, for example, may comprise supply voltage electrodes (e.g., VSS, VDD, etc.), although subject matter is not limited in scope in this respect.

As discussed herein, NSW extension across power rail techniques may be introduced and/or implemented to achieve larger active diffusion structures. Example 1.5H cells, such as described herein, may have higher drive strength, more skewed ratio, and/or lower area utilization as compared with a more standard cell (e.g., single height cell), for example. Placement challenges for 1.5H cells may be addressed via 0.5H filler cells, 1.5H filler cells, and/or 2.0H filler cells, for example, to enable cell transitions as well as to enable further area utilization improvements and/or optimization, in embodiments. 1.5H cells, such as the examples described and depicted herein, may improve device performance and/or may enable advanced processes to scale down further, in embodiments. Of course, these are merely example benefits and/or advantages that may be realized through 1.5H cells such as those described herein.

In the context of the present patent application, the term “connection,” the term “component” and/or similar terms are intended to be physical, but are not necessarily always tangible. Whether or not these terms refer to tangible subject matter, thus, may vary in a particular context of usage. As an example, a tangible connection and/or tangible connection path may be made, such as by a tangible, electrical connection, such as an electrically conductive path comprising metal or other conductor, that is able to conduct electrical current between two tangible components. Likewise, a tangible connection path may be at least partially affected and/or controlled, such that, as is typical, a tangible connection path may be open or closed, at times resulting from influence of one or more externally derived signals, such as external currents and/or voltages, such as for an electrical switch. Non-limiting illustrations of an electrical switch include a transistor, a diode, etc. However, a “connection” and/or “component,” in a particular context of usage, likewise, although physical, can also be non-tangible, such as a connection between a client and a server over a network, which generally refers to the ability for the client and server to transmit, receive, and/or exchange communications, as discussed in more detail later.

In a particular context of usage, such as a particular context in which tangible components are being discussed, therefore, the terms “coupled” and “connected” are used in a manner so that the terms are not synonymous. Similar terms may also be used in a manner in which a similar intention is exhibited. Thus, “connected” is used to indicate that two or more tangible components and/or the like, for example, are tangibly in direct physical contact. Thus, using the previous example, two tangible components that are electrically connected are physically connected via a tangible electrical connection, as previously discussed. However, “coupled,” is used to mean that potentially two or more tangible components are tangibly in direct physical contact. Nonetheless, is also used to mean that two or more tangible components and/or the like are not necessarily tangibly in direct physical contact, but are able to co-operate, liaise, and/or interact, such as, for example, by being “optically coupled.” Likewise, the term “coupled” is also understood to mean indirectly connected. It is further noted, in the context of the present patent application, since memory, such as a memory component and/or memory states, is intended to be non-transitory, the term physical, at least if used in relation to memory necessarily implies that such memory components and/or memory states, continuing with the example, are tangible.

In the present patent application, in a particular context of usage, such as a situation in which tangible components (and/or similarly, tangible materials) are discussed above, a distinction exists between being “on” and being “over.” As an example, deposition of a substance “on” a substrate refers to a deposition involving direct physical and tangible contact without an intermediary, such as an intermediary substance, between the substance deposited and the substrate in this latter example; nonetheless, deposition “over” a substrate, while understood to potentially include deposition “on” a substrate (since being “on” may also accurately be described as being “over”), is understood to include a situation in which one or more intermediaries, such as one or more intermediary substances, are present between the substance deposited and the substrate so that the substance deposited is not necessarily in direct physical and tangible contact with the substrate.

A similar distinction is made in an appropriate particular context of usage, such as in which tangible materials and/or tangible components are discussed, between being “beneath” and being “under.” While “beneath,” in such a particular context of usage, is intended to necessarily imply physical and tangible contact (similar to “on,” as just described), “under” potentially includes a situation in which there is direct physical and tangible contact, but does not necessarily imply direct physical and tangible contact, such as if one or more intermediaries, such as one or more intermediary substances, are present. Thus, “on” is understood to mean “immediately over” and “beneath” is understood to mean “immediately under.”

It is likewise appreciated that terms such as “over” and “under”,” as used herein, are understood in a similar manner as the terms “up,” “down,” “top,” “bottom,” and so on, previously mentioned. These terms may be used to facilitate discussion, but are not intended to necessarily restrict scope of claimed subject matter. For example, the term “over,” as an example, is not meant to suggest that claim scope is limited to only situations in which an embodiment is right side up, such as in comparison with the embodiment being upside down, for example. An example includes an underlayment embodiment, as one illustration, in which, for example, orientation at various times (e.g., during fabrication or application) may not necessarily correspond to orientation of a final product. Thus, if an object, as an example, is within applicable claim scope in a particular orientation, such as upside down, as one example, likewise, it is intended that the latter also be interpreted to be included within applicable claim scope in another orientation, such as right side up, again, as an example, and vice-versa, even if applicable literal claim language has the potential to be interpreted otherwise. Of course, again, as always has been the case in the specification of a patent application, particular context of description and/or usage provides helpful guidance regarding reasonable inferences to be drawn.

It is further noted that the terms “type” and/or “like,” as used herein, such as with a feature, structure, characteristic, and/or the like, means at least partially of and/or relating to the feature, structure, characteristic, and/or the like in such a way that presence of minor variations, even variations that might otherwise not be considered fully consistent with the feature, structure, characteristic, and/or the like, do not in general prevent the feature, structure, characteristic, and/or the like from being of a “type” and/or being “like,” if the minor variations are sufficiently minor so that the feature, structure, characteristic, and/or the like would still be considered to be substantially present with such variations also present. It should be noted that the specification of the present patent application merely provides one or more illustrative examples and claimed subject matter is intended to not be limited to one or more illustrative examples; however, again, as has always been the case with respect to the specification of a patent application, particular context of description and/or usage provides helpful guidance regarding reasonable inferences to be drawn.

Unless otherwise indicated, in the context of the present patent application, the term “or” if used to associate a list, such as A, B, or C, is intended to mean A, B, and C, here used in the inclusive sense, as well as A, B, or C, here used in the exclusive sense. With this understanding, “and” is used in the inclusive sense and intended to mean A, B, and C; whereas “and/or” can be used in an abundance of caution to make clear that all of the foregoing meanings are intended, although such usage is not required. In addition, the term “one or more” and/or similar terms is used to describe any feature, structure, characteristic, and/or the like in the singular, “and/or” is also used to describe a plurality and/or some other combination of features, structures, characteristics, and/or the like. Likewise, the term “based on” and/or similar terms are understood as not necessarily intending to convey an exhaustive list of factors, but to allow for existence of additional factors not necessarily expressly described.

Furthermore, it is intended, for a situation that relates to implementation of claimed subject matter and is subject to testing, measurement, and/or specification regarding degree, to be understood in the following manner. As an example, in a given situation, assume a value of a physical property is to be measured. If alternatively reasonable approaches to testing, measurement, and/or specification regarding degree, at least with respect to the property, continuing with the example, is reasonably likely to occur to one of ordinary skill, at least for implementation purposes, claimed subject matter is intended to cover those alternatively reasonable approaches unless otherwise expressly indicated. As an example, if a plot of measurements over a region is produced and implementation of claimed subject matter refers to employing a measurement of slope over the region, but a variety of reasonable and alternative techniques to estimate the slope over that region exist, claimed subject matter is intended to cover those reasonable alternative techniques unless otherwise expressly indicated.

To the extent claimed subject matter is related to one or more particular measurements, such as with regard to physical manifestations capable of being measured physically, such as, without limit, temperature, pressure, voltage, current, electromagnetic radiation, etc., it is believed that claimed subject matter does not fall with the abstract idea judicial exception to statutory subject matter. Rather, it is asserted, that physical measurements are not mental steps and, likewise, are not abstract ideas.

It is noted, nonetheless, that a typical measurement model employed is that one or more measurements may respectively comprise a sum of at least two components. Thus, for a given measurement, for example, one component may comprise a deterministic component, which in an ideal sense, may comprise a physical value (e.g., sought via one or more measurements), often in the form of one or more signals, signal samples and/or states, and one component may comprise a random component, which may have a variety of sources that may be challenging to quantify. At times, for example, lack of measurement precision may affect a given measurement. Thus, for claimed subject matter, a statistical or stochastic model may be used in addition to a deterministic model as an approach to identification and/or prediction regarding one or more measurement values that may relate to claimed subject matter.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define a HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioral representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Embodiments may also be described, at least in part, by the following numbered clauses:

Clause 1. An integrated circuit device, comprising: a first cell having a first height that is 1.5 times of a standard cell height, wherein the first cell comprises a first diffusion structure of a first diffusion type aligned in a first direction and a second diffusion structure of a second diffusion type aligned in the first direction; and a second cell having a second height that is one of 0.5 or 1.5 times the standard cell height, wherein a top portion of the second cell abuts a bottom portion of the first cell.

Clause 2. The integrated circuit device of clause 1, wherein a width of the first diffusion structure of the first diffusion type is greater than a width of the second diffusion structure of the second diffusion type, and wherein at least a portion of the first diffusion structure of the first diffusion type is positioned across a power rail.

Clause 3. The integrated circuit device of any of the previous clauses, wherein the first diffusion type comprises a P-type diffusion and the second diffusion type comprises an N-type diffusion.

Clause 4. The integrated circuit device of any of the previous clauses, wherein the first diffusion type comprises an N-type diffusion and the second diffusion type comprises a P-type diffusion.

Clause 5. The integrated circuit device of any of the previous clauses, wherein the first diffusion structure of the first diffusion type comprises a first plurality of nanosheets and/or nanowires and wherein the second diffusion structure of the second diffusion type comprises a second plurality of nanosheets and/or nanowires.

Clause 6. The integrated circuit device of any of the previous clauses, wherein a width of the first diffusion structure of the first diffusion type comprises a nanosheet width (NSW) of approximately 65 nm.

Clause 7. The integrated circuit device of any of the previous clauses, wherein a width of the second diffusion structure comprises a nanosheet width (NSW) of approximately 35 nm.

Clause 8. The integrated circuit device of any of the previous clauses, further comprising a layout including the first cell and the second cell, wherein a bottom portion of the second cell abuts a top portion of a third cell having a third height that is one of an integer multiple of the standard cell height or an even integer multiple of 1.5 times the standard cell height.

Clause 9. The integrated circuit device of any of the previous clauses, wherein the layout further comprises at least a fourth 1.0H cell and at least a fifth 2.0H cell abutting left/right one or more of the first and second 1.5H cells.

Clause 10. The integrated circuit device of any of the previous clauses, wherein the first cell abuts left/right the fourth 1.0H cell, and wherein the layout further comprises a first filler cell to enable a transition from one or more diffusion structures of the fourth 1.0H cell to one or more diffusion structures of the first cell.

Clause 11. The integrated circuit device of any of the previous clauses, wherein the first filler cell comprises a 1.5H filler cell.

Clause 12. The integrated circuit device of any of the previous clauses, wherein the second cell abuts left/right the at least the fifth 2.0H cell, and wherein the layout further comprises a second filler cell to enable a transition from one or more diffusion structures of the at least the fifth 2.0H cell to one or more diffusion structures of the second cell.

Clause 13. The integrated circuit device of any of the previous clauses, wherein the second filler cell comprises a 2.0H filler cell.

Clause 14. The integrated circuit device of any of the previous clauses, further comprising a layout including a plurality of 1.0H cells abutting left/right a plurality of 1.5H cells, wherein the layout further comprises a plurality of 0.5H filler cells and a plurality of 1.0H filler cells to enable transitions from a plurality of diffusion structures of the plurality of 1.0H cells to a plurality of diffusion structures of the plurality of 1.5H cells.

Clause 15. The integrated circuit device of any of the previous clauses, further comprising a layout including a plurality of 1.0H cells abutting left/right a plurality of 1.5H cells, wherein the layout further comprises a plurality of 1.5H filler cells to enable transitions from a plurality of diffusion structures of the plurality of 1.0H cells to a plurality of diffusion structures of the plurality of 1.5H cells.

Clause 16. The integrated circuit device of any of the previous clauses, further comprising a layout including a one or more third cells abutting left/right one or more fourth cells with no filler cells to transition between the one or more third cells and the one or more fourth cells.

Clause 17. The integrated circuit device of any of the previous clauses, further comprising a layout further including one or more 0.5H cells or 2.5H cells, or any combination thereof.

Clause 18. The integrated circuit device of any of the previous clauses, wherein at least the first cell is implemented utilizing GAA FET, finFET, and/or CFET technologies.

Clause 19. A method, comprising: forming a first cell having a first height that is 1.5 times of a standard cell height, wherein the first cell comprises a first diffusion structure of a first diffusion type aligned in a first direction and a second diffusion structure of a second diffusion type aligned in the first direction; and forming a second cell having a second height that is one of 0.5 or 1.5 times the standard cell height, wherein a top portion of the second cell abuts a bottom portion of the first cell.

Clause 20. A non-transitory computer-readable medium to store computer-readable code for fabrication of an apparatus comprising: a first cell having a height that is 1.5 times of a standard cell height, wherein the first cell comprises a first diffusion structure of a first diffusion type aligned in a first direction and a second diffusion structure of a second diffusion type aligned in the first direction; and a second cell having a second height that is one of 0.5 or 1.5 times the standard cell height, wherein a top portion of the second cell abuts a bottom portion of the first cell.

In the preceding description, various aspects of claimed subject matter have been described. For purposes of explanation, specifics, such as amounts, systems and/or configurations, as examples, were set forth. In other instances, well-known features were omitted and/or simplified so as not to obscure claimed subject matter. While certain features have been illustrated and/or described herein, many modifications, substitutions, changes and/or equivalents will now occur to those skilled in the art. It is, therefore, to be understood that the appended claims are intended to cover all modifications and/or changes as fall within claimed subject matter.

What is claimed is:

1. An integrated circuit device, comprising:
a first cell having a first height that is 1.5 times of a standard cell height, wherein the first cell comprises a first diffusion structure of a first diffusion type aligned in a first direction and a second diffusion structure of a second diffusion type aligned in the first direction; and
a second cell having a second height that is one of 0.5 or 1.5 times the standard cell height, wherein a top portion of the second cell abuts a bottom portion of the first cell.

2. The integrated circuit device of claim 1, wherein a width of the first diffusion structure of the first diffusion type is greater than a width of the second diffusion structure of the second diffusion type, and wherein at least a portion of the first diffusion structure of the first diffusion type is positioned across a power rail.

3. The integrated circuit device of claim 2, wherein the first diffusion type comprises a P-type diffusion and the second diffusion type comprises an N-type diffusion.

4. The integrated circuit device of claim 2, wherein the first diffusion type comprises an N-type diffusion and the second diffusion type comprises a P-type diffusion.

5. The integrated circuit device of claim 1, wherein the first diffusion structure of the first diffusion type comprises a first plurality of nanosheets and/or nanowires and wherein the second diffusion structure of the second diffusion type comprises a second plurality of nanosheets and/or nanowires.

6. The integrated circuit device of claim 1, wherein a width of the first diffusion structure of the first diffusion type comprises a nanosheet width (NSW) of approximately 65 nm.

7. The integrated circuit device of claim 6, wherein a width of the second diffusion structure comprises a nanosheet width (NSW) of approximately 35 nm.

8. The integrated circuit device of claim 1, further comprising a layout including the first cell and the second cell, wherein a bottom portion of the second cell abuts a top portion of a third cell having a third height that is one of an integer multiple of the standard cell height or an even integer multiple of 1.5 times the standard cell height.

9. The integrated circuit device of claim 8, wherein the layout further comprises at least a fourth 1.0H cell and at least a fifth 2.0H cell abutting left/right one or more of the first and second cells.

10. The integrated circuit device of claim 9, wherein the first cell abuts left/right the fourth 1.0H cell, and wherein the layout further comprises a first filler cell to enable a transition from one or more diffusion structures of the fourth 1.0H cell to one or more diffusion structures of the first cell.

11. The integrated circuit device of claim 10, wherein the first filler cell comprises a 1.5H filler cell.

12. The integrated circuit device of claim 11, wherein the second cell abuts left/right the at least the fifth 2.0H cell, and wherein the layout further comprises a second filler cell to enable a transition from one or more diffusion structures of the at least the fifth 2.0H cell to one or more diffusion structures of the second cell.

13. The integrated circuit device of claim 12, wherein the second filler cell comprises a 2.0H filler cell.

14. The integrated circuit device of claim 1, further comprising a layout including a plurality of 1.0H cells abutting left/right a plurality of 1.5H cells, wherein the layout further comprises a plurality of 0.5H filler cells and a plurality of 1.0H filler cells to enable transitions from a plurality of diffusion structures of the plurality of 1.0H cells to a plurality of diffusion structures of the plurality of 1.5H cells.

15. The integrated circuit device of claim 1, further comprising a layout including a plurality of 1.0H cells abutting left/right a plurality of 1.5H cells, wherein the layout further comprises a plurality of 1.5H filler cells to enable transitions from a plurality of diffusion structures of the plurality of 1.0H cells to a plurality of diffusion structures of the plurality of 1.5H cells.

16. The integrated circuit device of claim 1, further comprising a layout including a one or more third cells abutting left/right one or more fourth cells with no filler cells to transition between the one or more third cells and the one or more fourth cells.

17. The integrated circuit device of claim 1, further comprising a layout further including one or more 0.5H cells or 2.5H cells, or any combination thereof.

18. The integrated circuit device of claim 1, wherein at least the first cell is implemented utilizing GAA FET, finFET, and/or CFET technologies.

19. A method, comprising:
forming a first cell having a first height that is 1.5 times of a standard cell height, wherein the first cell comprises a first diffusion structure of a first diffusion type aligned in a first direction and a second diffusion structure of a second diffusion type aligned in the first direction; and
forming a second cell having a second height that is one of 0.5 or 1.5 times the standard cell height, wherein a top portion of the second cell abuts a bottom portion of the first cell.

20. A non-transitory computer-readable medium to store computer-readable code for fabrication of an apparatus comprising:
a first cell having a height that is 1.5 times of a standard cell height, wherein the first cell comprises a first diffusion structure of a first diffusion type aligned in a first direction and a second diffusion structure of a second diffusion type aligned in the first direction; and
a second cell having a second height that is one of 0.5 or 1.5 times the standard cell height, wherein a top portion of the second cell abuts a bottom portion of the first cell.
